(19) United States
(12) Patent Application Publication
(10) Pub. No.: US 2007/0072339 A1
(43) Pub. Date: Mar. 29, 2007

(54) PROCESS FOR FABRICATING CHIP PACKAGE STRUCTURE

(76) Inventors: Kai-Chi Chen, Nantou County (TW); Shu-Chen Huang, Keelung City (TW); Hsun-Tien Li, Hsinchu City (TW); Tzong-Ming Lee, Hsinchu City (TW); Taro Fukui, Osaka (JP); Tomoaki Nemoto, Osaka (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,106

(22) Filed: Jun. 23, 2006

Related U.S. Application Data
(62) Division of application No. 10/707,687, filed on Jan. 5, 2004, now abandoned.

(30) Foreign Application Priority Data
Apr. 22, 2003 (JP) 2003-117601
Oct. 24, 2003 (TW) 92129524

(51) Int. Cl. H01L 21/00

(52) U.S. Cl. 438/106; 438/121

(57) ABSTRACT

A process for fabricating a chip package structure is disclosed. To fabricate the chip package structure, a carrier and a plurality of chips are provided. Each chip has an active surface and at least one of the active surfaces has a plurality of bumps thereon. The chips and the carrier are electrically connected together. Thereafter, a heat sink is attached to the back of the chips and then at least one heat-resistant buffering film is formed over part of the heat sink surface. An encapsulating material layer is formed over the carrier and filling bonding gaps between the chips and the carrier. The encapsulating material within the bonding gaps has a thickness. The maximum diameter of particles constituting the encapsulating material layer is less than half of the said thickness.

### CROSS-REFERENCE TO RELATED APPLICATION

This application is a divisional of a prior application Ser. No. 10/707,687, filed Jan. 5, 2004 claims the priority benefit of Japan application serial no. 2003-117601, filed Apr. 22, 2003 and Taiwan application serial no. 92129524, filed Oct. 24, 2003. All disclosures are incorporated herewith by reference.

### BACKGROUND OF THE INVENTION

1. Field of the Invention

The present invention relates to a chip package structure and process of fabricating the same. More particularly, the present invention relates to a chip package structure with superior heat-dissipating capacity and process of fabricating the same.

2. Description of the Related Art

In this fast and ever-changing society, information matters to all people. Many types of portable electronic devices are produced which attempts to catch up with our desires to transmit and receive more data. Nowadays, manufacturers have to factor into their chip package many design concepts such as digital architecture, network organization, local area connection and personalized electronic devices. To do so demands special consideration in every aspect of the design process that affects the processing speed, multi-functional capability, integration level, weight and cost of the chip package. In other words, chip packages must be miniaturized and densified. Flip chip (F/C) bonding technique, through the bonding of bumps to a carrier, is currently one of the principle means of reducing overall wiring length over the conventional wire-bonding method. With a shortening of wiring length in a F/C package, signal transmission rate between the chip and a carrier is increased. Thus, F/C packaging technique is one of the most popular methods of forming high-density packages. However, as density of each package continues to increase, heat dissipation becomes a major problem facing chip manufacturers.

FIG. 1 is a schematic cross-sectional view of a conventional chip package with a wire bonding structure. As shown in FIG. 1, the chip packages has a chip 20 with an active surface 22 having a plurality of bonding pads (not shown) thereon. The back of the chip 20 is attached to a carrier 30 so that the active surface 22 faces upwards. The carrier 30 also has a plurality of contact pads (not shown) thereon. A plurality of conductive wires 24 is deployed to connect various the bonding pads with corresponding contact pads so that the chip 20 and the carrier 30 are electrically connected together. Furthermore, an array of solder balls 32 is attached to the carrier 30 on the far side of the chip 20. In other words, the chip package structure 10 has a ball grid array (BGA) packaging structure for connecting electrically with a printed circuit board (PCB) (not shown). In addition, a encapsulating material layer 34 is formed over the carrier 30 to cover the chip 20 and the conductive wires 24. Since the encapsulating material layer 34 is fabricated with material having poor thermal conductivity, the chip package structure 10 has a low heat dissipating capacity.

FIG. 2 is a schematic cross-sectional view of a chip package structure fabricated through a conventional flip-chip packaging technique. As shown in FIG. 2, the chip package structure 40 mainly comprises a chip 50, a carrier 60 and an encapsulating material layer 65. The chip 50 has an active surface 52 with a plurality of bonding pads (not shown) thereon. The carrier 60 also has a plurality of contact pads (not shown) thereon. A plurality of bumps 54 is positioned on the respective bonding pads on the active surface 52 of the chip 50. Furthermore, the bonding pads on the chip 50 and the contact pads on the carrier 60 are electrically connected together through the bumps 54. On the far side of the carrier 60 away from the chip 50, an array of solder balls 62 is attached.

To prevent any damage to the chip 50 due to an incursion of moisture and any damage to the bumps 54 due to mechanical stress, an encapsulating material layer 65 is formed within the bonding gap between the chip 50 and the carrier 60. Conventionally, the encapsulating material layer 65 is formed by channeling a liquid encapsulating material with low viscosity into the bonding gap between the chip 50 and the carrier 60 through capillary effect and then curing the injected material afterwards.

The flip-chip package structure 40 as shown in FIG. 2 has an electrical performance better than the conventional wire-bonded chip package structure 10 in FIG. 1. Furthermore, the flip-chip package structure 40 has an ultra-thin thickness suitable for embedding inside a slim device. However, it takes considerable time to fill up the bonding gap between the chip 50 and the carrier 60 with liquid encapsulating material through capillary effect alone. Hence, this method is unsuitable for economic mass production. Moreover, the number of bumps 54 inside the bonding gap, the distribution of the bumps 54 inside the package as well as the distance of separation between the flip chip 50 and the carrier 60 are some of the major factors affecting the capillary flow of liquid encapsulating material. Because the capillary effect is utilized to draw liquid encapsulating material into the space between the chip 50 and the carrier 60, any variation of the liquid flow conditions is likely to hinder the filling process leading to the possibility of formation of voids. In other words, reliability of the package will be affected. In addition, the chip 50 within the chip package structure 40 is directly exposed. Hence, the chip 50 could be damaged when markings are imprinted on the surface of the chip 50 or the chip package structure 40 is picked up using a suction pad gripping the back of the chip 50.

FIG. 3 is a schematic cross-sectional view of a conventional thermal enhanced ball grid array package (TEBGA). As shown in FIG. 3, the chip package structure 70 comprises a carrier 90, a chip 80, a heat sink 85, a plurality of conductive wires 84, an array of solder balls 92 and an encapsulating material layer 95. The chip 80 has an active surface 82 with a plurality of bonding pads (not shown) thereon. The heat sink 85 is positioned on the back of the chip 80 as well as the carrier 90. The heat sink 85 and the chip 80 are attached through a thermal conductive adhesive layer 87. The positive surface of the carrier 90 has a plurality of contact pads (not shown) thereon. One end of each conductive wire 84 is bonded to a bonding pad on the chip 80 while the other end is bonded to a corresponding contact pad on the carrier 90 so that the chip 80 and the carrier 90 are connected electrically. The array of solder balls 92 is bonded to positive surface of the carrier 90. The solder balls 92 are electrically connected to the chip 80 via the conductive wires 84. Furthermore, the encapsulating material layer 95 encloses the chip 80, the conductive wires 84 and the contact pads on the carrier 90 to form a protective cover.

Although the aforementioned chip package structure 70 can have a high heat-dissipating capacity, the package also requires a large surface area. Hence, producing a package with a high input/output pin count is difficult. Moreover, the assembling process is rather complicated so that the production cycle is quite long.

### SUMMARY OF THE INVENTION

Accordingly, at least one objective of the present invention is to provide a chip package structure and process of fabricating the same that combine the superior electrical performance of a flip-chip bonded device with the high heat dissipating capacity of a package with a heat sink.

To achieve these and other advantages and in accordance with the purpose of the invention, as embodied and broadly described herein, the invention provides a chip package structure. The chip package structure mainly comprises a carrier, a chip, a heat sink and an encapsulating material layer. The chip has an active surface with a plurality of bumps thereon. The active surface of the chip is flipped over and bonded to the carrier in a flip-chip bonding process so that the chip and the carrier are electrically connected. The heat sink is set over the chip. The heat sink has an area larger than the chip. The encapsulating material layer completely fills a bonding gap between the chip and the carrier and covers the carrier. Furthermore, the encapsulating material layer is formed in a simultaneous molding process and at least part of the surface of the heat sink away from the chip is exposed.

The encapsulating material layer within the bonding gap between the chip and the carrier has a thickness. The maximum diameter of particles constituting the encapsulating material layer is less than 0.5 times the said thickness. The chip package structure of this embodiment further comprises a thermal conductive adhesive layer set between the chip and the heat sink.

This invention also provides an alternative chip package structure. The chip package structure mainly comprises a carrier, a chipset, a heat sink and an encapsulating material layer. The chipset is set over and electrically connected to the carrier. The chipset comprises a plurality of chips and at least one of the chips is flip-chip bonded to the carrier or another chip so that a flip-chip bonding gap is created. The heat sink is set over the chipset. The heat sink has an area larger than the chipset. The encapsulating material layer completely fills the bonding gap between the chip and the carrier and covers the carrier. Furthermore, the encapsulating material layer is formed in a simultaneous molding process and at least part of the surface of the heat sink away from the chip is exposed.

The encapsulating material layer within the bonding gap between the chip and the carrier has a thickness. The maximum diameter of particles constituting the encapsulating material layer is less than 0.5 times the said thickness. The chip package structure of this embodiment further comprises a thermal conductive adhesive layer set between the uppermost chip of the chipset and the heat sink.

In addition, the chipset of this embodiment comprises a first chip and a second chip. The first chip has a first active surface. The first chip is attached to the carrier such that the first active surface is away from the carrier. The second chip has a second active surface with a plurality of bumps thereon. The second chip is bonded and electrically connected to the first chip in a flip-chip bonding process. The bumps set a flip-chip bonding gap between the first and the second chip.

Furthermore, the chipset further comprises a plurality of conductive wires. Each conductive wire connects a bonding pad on the first chip electrically with a corresponding contact pad on the carrier.

Alternatively, the chipset of this embodiment comprises a first chip, a second chip and a third chip. The first chip has a first active surface with a plurality of first bumps thereon. The first chip is bonded and electrically connected to the carrier in a flip-chip bonding process. The second chip has a second active surface. The second chip is attached to the first chip such that the second active surface is away from the first chip. The third chip has a third active surface with a plurality of second bumps thereon. The third chip is bonded and electrically connected to the second chip in a flip-chip bonding process. The first bumps set a flip-chip bonding gap between the first chip and the carrier and the second bumps set a flip-chip bonding gap between the second chip and the third chip.

Furthermore, the chipset further comprises a plurality of conductive wires. Each conductive wire connects a bonding pad on the second chip electrically with a corresponding contact pad on the carrier.

In the aforementioned embodiments of the chip package structure, the encapsulating material is made from resin and the heat sink is made from a metal, for example. The chip package structure may further comprise an array of solder balls and at least a passive component. The solder balls are attached to the surface of the carrier away from the chip. The passive components are set over and electrically connected to the carrier. The carrier can be a packaging substrate or a lead frame, for example.

This invention also provides a process for fabricating a chip package structure. First, a carrier and a plurality of chips are provided. Each chip has an active surface and at least one of the active surfaces has a plurality of bumps thereon. Thereafter, the chips and the carrier are electrically connected together. A heat sink is attached to the back of a chip through a thermal conductive adhesive layer. A heat-resistant buffering film is formed over part of the heat sink surface. Finally, an encapsulating material layer is formed covering the carrier and filling a flip-chip bonding gap between the chip and the carrier.

Furthermore, the encapsulating material layer is formed by performing a reduced-pressure transfer molding process. After forming the encapsulating material layer, the carrier is singulated to form a plurality of chip package structures. The reduced-pressure transfer molding process is carried out at a pressure below 20 mm-Hg (Torr) and a temperature at least 10° C. lower than the melting point of the bumps. Moreover, if the encapsulating material layer within the bonding gap between the chip and the carrier has a thickness, maximum diameter of particles constituting the encapsulating material layer must be less than 0.5 times the said thickness.

In brief, the chip package structure incorporates a heat sink having an area larger than the chip. Hence, this invention provides an ideal thermal conductive pathway for distributing the heat generated by a high-pin-count chip package structure. Therefore, operational speed and reliability of the chip package structure is improved. Furthermore, the chip packaging process has the advantage of having a high productivity.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional chip package structure with a wire bonding structure.

FIG. 2 is a schematic cross-sectional view of a chip package structure fabricated through a conventional flip-chip packaging technique.

FIG. 3 is a schematic cross-sectional view of a conventional thermal enhanced ball grid array package (TEBGA).

FIGS. 4A through 4I are schematic cross-sectional views of a series of chip package structures according a first preferred embodiment of this invention.

FIGS. 5 and 6 are schematic cross-sectional views of two chip package structures according a second preferred embodiment of this invention.

FIG. 7A is a schematic cross-sectional view of a finished product fabricated according to a chip package fabrication process according to this invention.

FIG. 7B is a schematic cross-sectional view of a singulated product fabricated according to a chip package fabrication process according to this invention.

FIG. 8 is a schematic cross-sectional view showing a mold for forming the encapsulating material layer of a chip package structure in a reduced-pressure transfer molding process according to this invention.

FIG. 9 is a table showing conditions and material properties for performing a transfer molding process.

FIG. 10 is a table showing performance and reliability of chip package structures after the transfer molding process.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

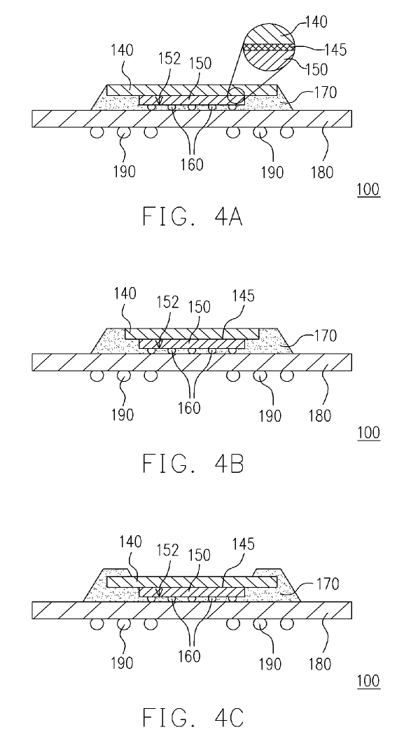

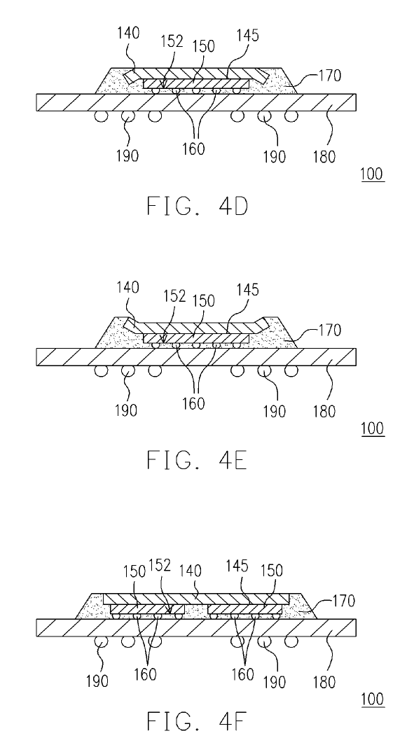

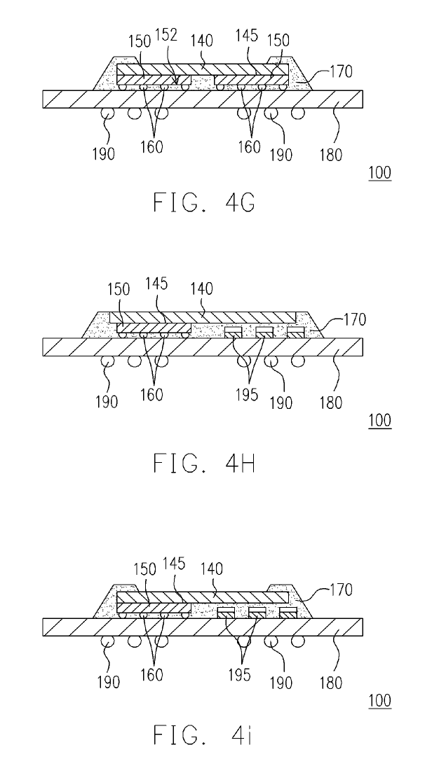

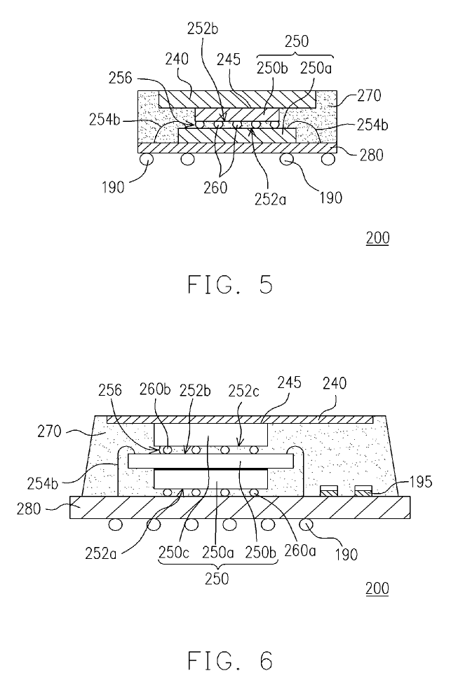

FIGS. 4A through 4I are schematic cross-sectional views of a series of chip package structures according a first preferred embodiment of this invention. As shown in FIGS. 4A through 4I, the chip package structure 100 mainly comprises a carrier 180, a chip 150, a heat sink 140 and an encapsulating material layer 170. The carrier 180 is, for example, an organic substrate, a ceramic substrate, a flexible substrate or a lead frame used in a flip-chip quad flat non-leaded (F/C QFN) packaging process. The carrier 180 has an upper and a lower surface with a plurality of contact pads (not shown) thereon.

The chip 150 has an active surface 152 with a plurality of bonding pads (not shown) thereon. A plurality of bumps 160 is attached to the bonding pads on the active surface 152 of the chip 150. The active surface 152 of the chip 150 is flipped over to face the carrier 180. Thereafter, the chip 150 is bonded to the carrier 180 through the bumps 160 on the bonding pads so that the chip 150 and the carrier 180 are electrically connected. In other words, the chip package structure 100 of this embodiment includes at least a chip 150 bonded to the upper surface of a carrier 180 using a flip-chip bonding technique. However, aside from the chip 150, this invention also permits the mounting of other chips or passive components such as resistors or capacitors on the carrier 180 within the package structure 100.

The heat sink 140 is set over the chip 150. The heat sink 140 has an area larger than the chip 150 so that a higher heat dissipating capacity is provided. Furthermore, the heat sink 140 is not limited to a single integrative unit. The heat sink 140 may comprise a multiple of individual heat sinks providing more flexibility to the design of the chip package structure.

In addition, the encapsulating material layer 170 completely fills a bonding gap between the chip 150 and the carrier 180 and covers the carrier 180. The encapsulating material layer 170 is formed in a simultaneous molding process using a resin, for example.

The heat sink 140 is fabricated using a metallic material, for example. In this invention, the heat sink 140 has an area larger than the chip 150 so that the heat generated by the chip 150 is able to spread out into a large area. Therefore, metallic materials with high thermal conductivity including, for example, copper plate, aluminum plate, iron plate, nickel plate or other gold electroplated thereon is preferred. In addition, the heat sink 140 must withstand the pressure encountered during a molding process. Hence, the heat sink 140 is preferably fabricated using a high strength material with anti-warping capacity. Although there is a variety of high thermal conductive metallic material to choose from, the heat sink 140 preferably has a thickness between 0.1˜0.6 mm. Moreover, to ensure a strong adhesion between the encapsulating material layer 170 and the heat sink 140, the heat sink 140 may undergo a chemical treatment, a roughening process or a gold plating operation prior to the molding process.

To ensure the formation of a suitable bond between the heat sink 140 and the chip 150, a thermal conductive adhesive layer 145 is applied to the junction between the heat sink 140 and the chip 150 (as shown in an enlarged portion of FIG. 4A). Typically, the thermal conductive adhesive layer 145 is a layer of silicone, silver epoxy, soldering paste or other highly thermal conductive materials, for example.

The chip package structure 100 may further comprise an array of solder balls 190. The solder balls 190 are attached to the contact pads on the lower surface of the carrier 180 for subsequently connecting with a printed circuit board, for example.

Among the chip package structures in FIGS. 4A through 4I, the chip package structures 100 in FIGS. 4A˜4E and 4H˜4I has a single chip 150 and the chip package structures 100 in FIGS. 4F˜4G has two chips 150. Obviously, the number of chips inside a package is not limited as such. More chips may be enclosed within each package. In FIGS. 4C, 4D, 4G and 4I, the encapsulating material layer 170 of the chip package structures 100 covers the peripheral portion of the upper surface of the heat sink 140 while the remaining upper surface is exposed. In FIGS. 4D and 4E, the peripheral region of the heat sink 140 has been processed to bend downward or upward. In FIGS. 4H and 4I, the chip package structure 100 further comprises at least a passive component 195 mounted on the upper surface of the carrier 180. Furthermore, the passive component 195 is electrically connected to the carrier 180. The aforementioned chip package structures 100 as shown in FIGS. 4A˜4I are variations of the same theme according to this invention.

FIGS. 5 and 6 are schematic cross-sectional views of two chip package structures according a second preferred embodiment of this invention. According to the second embodiment, a plurality of chips is stacked on top of a carrier. As shown in FIGS. 5 and 6, the chip package structure 200 mainly comprises a carrier 280, a chipset 250, a heat sink 240 and an encapsulating material layer 270. The chipset 250 comprises a plurality of chips and at least one of the chips is flip-chip bonded to the carrier 280 or another chip so that a flip-chip bonding gap 256 is created through the bumps. The heat sink 240 is set over the chipset 250. The encapsulating material layer 270 completely fills the flip-chip bonding gap 256 and covers the carrier 280. The encapsulating material layer 270 is formed in a simultaneous molding process. Furthermore, part of the surface of the heat sink 240 on the far side of the chipset 250 is exposed.

The encapsulating material layer 270 within the flip-chip bonding gap 256 has a thickness. Maximum diameter of particles constituting the encapsulating material layer 270 must be less than 0.5 times the said thickness of the bonding gap 256. To ensure the formation of a suitable bond between the heat sink 240 and the chipset 250, a thermal conductive adhesive layer 245 is applied to the junction between the heat sink 240 and the uppermost chip of the chipset 250. Typically, the thermal conductive adhesive layer 245 is a layer of silicone, silver epoxy, soldering paste or other highly thermal conductive materials, for example.

As shown in FIG. 5, the chipset 250 comprises a first chip 250a and a second chip 250b. The first chip 250a has a first active surface 252a. The first chip 250a is attached to the carrier 280 such that the first active surface 252a is away from the carrier 280. The second chip 250b has a second active surface 252b with a plurality of bumps 260 thereon. The second chip 250b is bonded and electrically connected to the first chip 250a in a flip-chip bonding process. The bumps 260 set a flip-chip bonding gap 256 between the first chip 250a and the second chip 250b.

Furthermore, the chipset 250 further comprises a plurality of conductive wires 254b. The carrier 280 has a plurality of contact pads (not shown) thereon. The solder balls 190 are attached to the contact pads on the lower surface of the carrier 280 which is similar or the same to the solder balls 190 shown in FIGS. 4A˜4I. The first active surface 252a of the first chip 250a and the second active surface 252b of the second chip 250b have a plurality of bonding pads (not shown) thereon. The bumps 260 on the second chip 250b are set in the flip-chip bonding gap 256 between the first chip 250a and the second chip 250b. In other words, the second chip 250b is flip-chip bonded to the first active surface 252a of the first chip 250a. Each conductive wire 254b electrically connects a bonding pad on the first chip 250a with a corresponding contact pad on the carrier 280.

As shown in FIG. 6, an alternative chipset 250 of this embodiment comprises a first chip 250a, a second chip 250b and a third chip 250c. The chipset 250 further includes a plurality of conductive wires 254b. The first chip 250a has a first active surface 252a with a plurality of first bumps 260a thereon. The first chip 250a is bonded and electrically connected to the carrier 280 in a flip-chip bonding process. The second chip 250b has a second active surface 252b. The second chip 250a is attached to the first chip 250a such that the second active surface 252b face towards a direction away from the first chip 250a. The conductive wires 254b connect the bonding pads on the second active surface 252b of the second chip 250b with corresponding contact pads on the carrier 280. The third chip 250c has a third active surface 252c with a plurality of second bumps 260b thereon. The third chip 250c is bonded and electrically connected to the second chip 250b in a flip-chip bonding process. The first bumps 260a are set in a flip-chip bonding gap between the first chip 250a and the carrier 280 and the second bumps are set in another flip-chip bonding gap 256 between the second chip 250b and the third chip 250c. In other words, the third chip 250c is flip-chip bonded to the second active surface 252b of the second chip 250b and the first chip 250a is flip-chip bonded to the carrier 280. The chip package structure 200 further comprises at least a passive component 195 mounted on the upper surface of the carrier 280 which is similar or the same to passive component 195 shown in FIG. 4H, and the passive component 195 is electrically connected to the carrier 280.

In the second embodiment, the number of chips within the chip package structure is increased. In addition, not all the chips have to be bonded to the carrier using the flip-chip bonding technique. In fact, the main characteristic of this invention is that the chip package structures has at least a chip bonded to a carrier or another chip using the flip-chip bonding technique. Furthermore, a heat sink is mounted on the top of the chip and an encapsulating material layer is formed over the carrier as well as inside the flip-chip bonding gap. Moreover, the encapsulating material layer is formed in a simultaneous molding process such that at least part of upper surface of the heat sink is exposed. Any chip package structure with the aforementioned characteristics should be counted as a design within the scope of this invention.

This invention also provides a process for fabricating the aforementioned chip packages structure. To fabricate the chip package structure, a carrier and a plurality of chips are provided. Each chip has an active surface and at least one of the active surfaces has a plurality of bumps thereon. The chips and the carrier are electrically connected together. Thereafter, a heat sink is attached to the back of the chips and then at least one heat-resistant buffering film is formed over part of the heat sink surface. An encapsulating material layer is formed over the carrier and filling bonding gaps between the chips and the carrier.

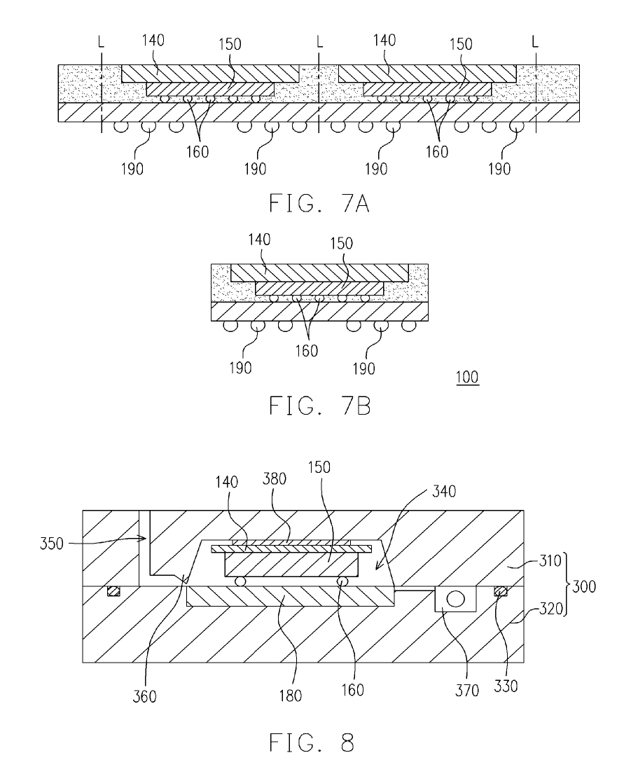

FIG. 7A is a schematic cross-sectional view of a finished product fabricated according to a chip package fabrication process according to this invention. FIG. 7B is a schematic cross-sectional view of a singulated product fabricated according to a chip package fabrication process according to this invention. As shown in FIGS. 7A and 7B, the encapsulated semi-finished product is diced along a series of cutting lines L to form a plurality of chip package structures 100. Each singulated chip package structure 100 at least comprises a chip 150. Although the encapsulating material layer 170 in FIG. 7A is shown to be a coherent mass, the mold for forming the encapsulating material layer 170 can be adjusted to form a plurality of independent encapsulating material layers 170. In other words, encapsulating material is prevented from entering the cutting zones so that total time for cutting out the entire chip package structures 100 is reduced.

It is to be noted that a reduced-pressure transfer molding process may be used to form the encapsulating material layer in the process of fabricating the chip package structure. In the reduced-pressure transfer molding process, the chips to be enclosed are placed inside a mold cavity. After reducing the pressure inside the mold cavity, encapsulant is channeled into the mold cavity. Thereafter, the mold is heated and pressurized so that the resin is cured. Ordinary transfer molding process has insufficient capacity for forming a fully filled encapsulating material layer in the flip-chip bonding gap or the over mold layer. On the other hand, if the pressure inside the mold cavity is allowed to lower to a level below 20 mm-Hg, the filling capability of the encapsulating material will improve considerably. Preferably, the mold cavity is set to a pressure below 10 mm-Hg.

FIG. 8 is a schematic cross-sectional view showing a mold for forming the encapsulating material layer of a chip package structure in a reduced-pressure transfer molding process according to this invention. As shown in FIG. 8, a mold 300 is placed inside a set of transfer molding equipment (not shown). The mold 300 comprises an upper mold section 310 and a lower mold section 320. To provide an effective vacuum when the upper mold 310 and the lower mold 320 are put together, the upper mold section 310, the lower mold section 320 and a vacuum rubber ring 330 inside the mold 300 are pressed to make a light contact. Air is drawn from a mold cavity 340 of the mold 300 using a vacuum pump (not shown) by way of a vacuum pipeline 370 so that the pressure inside the mold cavity 340 is reduced. Thereafter, plastic tablets (not shown) are deposited into a plastic injection pipeline 350 within the mold 300. Pumping continues for another 15 seconds to increase the degree of vacuum inside the mold cavity 340. In the meantime, the mold 300 is heated so that the plastic tablets melt to form a fluidic encapsulating material. Finally, the upper mold section 310 and the lower mold section 320 are tightly sealed and a plunger 360 is lifted so that the melt encapsulating material is channeled into the mold cavity 340. This completes a reduced-pressure transfer molding process.

During the reduced-pressure molding process, the mold is controlled at a temperature at least 10° C. below the melting point of the bumps 160. If temperature of the mold is higher than this value, the pressure generated by the melting encapsulating material may peel off the chip 150 when the bonding strength between the bumps 160 and the carrier 180 is not strong enough.

Furthermore, if part of the heat sink 140 needs to be exposed after the molding process, a heat-resistant buffering film 380 must be used. Without the heat-resistant buffering film 380, the exposed surface of the heat sink 140 may contain flush. On the other hand, if a pressure is directly applied to the heat sink 140 by adjusting the upper mold 310 simply to prevent the formation of flush, the molding pressure may act on the chip 150 via the heat sink 140 and cause some damage to the chip 150. Therefore, the heat-resistant buffering film 380 on the heat sink 140 is one of the most effective means of reducing the flush.

The heat-resistant buffering film 380 is typically a polyamide or fluorinated resin layer but is not limited thereto. In general, the heat-resistant buffering film 380 has a thickness between 25˜75 μm so that the buffering action according to this invention can be produced. In addition, the heat-resistant buffering film may be fabricated from a rubbery material such as fluorinated rubber.

In addition, according to the chip packaging process of this invention, the maximum diameter of particles constituting the encapsulating material is preferably less than 0.5 times the flip-chip bonding gap. If the encapsulating material contains particles with diameter greater than 0.5 times the flip-chip bonding gap, difficulties in filling the flip-chip bonding gap or the gap between the carrier and the heat sink may occur. Moreover, friction between the encapsulating material and chip surface may scratch and damage the chip leading to a drop in overall reliability of the package.

In the following, actual examples and contrast examples of this invention as well as their application results are described.

### EXAMPLE 1

Chips each having a total area 8 mm×8 mm, 800 lead-tin bumps (melting point 183° C., pitch separation 0.25 mm) and a thickness 0.3 mm are set as an array over a FR-5 carrier with an area 35 mm×35 mm, a thickness 0.4 mm. To provide a uniform distribution of current, aluminum wires are set on the surface of the chip. The flip-chip bonding gap is between 50 to 75 μm. A 22 mm×22 mm copper plate (heat sink) with a thickness of about 0.2 mm is provided. After plating a layer of nickel over the copper plate, a piece of conventional 20 mm width φPFA film (having a thickness 50 μm) is taped onto the copper plate. The lower surface of the copper plate is also roughened to increase bonding strength. The copper plate is attached to the chip using a conventional thermal conductive adhesive material. A set of transfer molding equipment with reduced-pressure molding capability is used to performing the reduced-pressure molding process. The pressure inside the mold cavity is reduced to an almost vacuum state of 1 mm-Hg during the molding process. The encapsulating material is CV8700F2 (having a maximum particle diameter 21 μm, average particle diameter 5 μm, all silicon filler) produced by Matsushita Electric Works, Ltd. The upper mold cavity has a thickness 0.6 mm and a total encapsulating area around 27 mm×27 mm. The molding process is carried out at 170° C. and a pressure of 70 kg/cm² for about 2 minutes. Thereafter, a post-curing process is carried out at a temperature of 175° C. for 4 hours to produce a chip package structure as shown in FIG. 4C.

### CONTRAST EXAMPLE 1

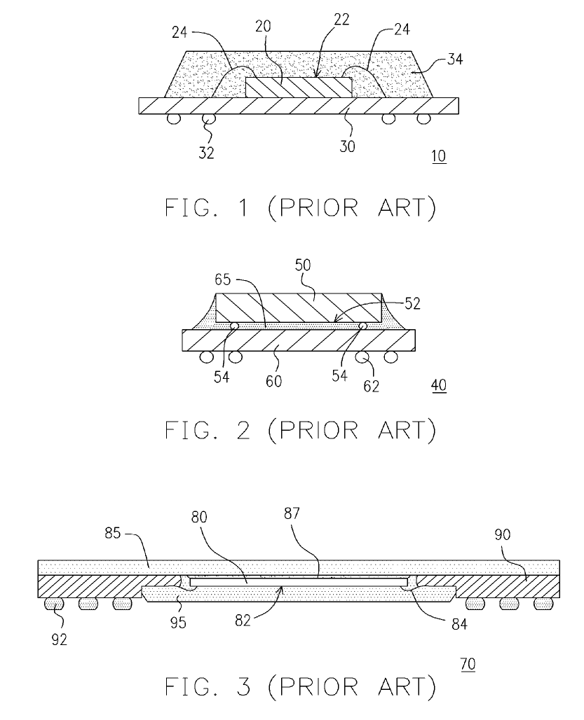

The same chip as in example 1 and conventional underfill material (Matsushita Electric Works product CV5183F) is used. Spot injection equipment is deployed to carry out the flip-chip bonding gap filling process. After curing the filling material at prescribed conditions, a chip package structure as shown in FIG. 2 is produced.

### CONTRAST EXAMPLE 2

The same chip and carrier as in example 1 is used. Aside from not providing a pressure reduction through a vacuum pump, all other aspects are identical. A chip package structure identical to FIG. 4C is produced.

### EXAMPLE 2

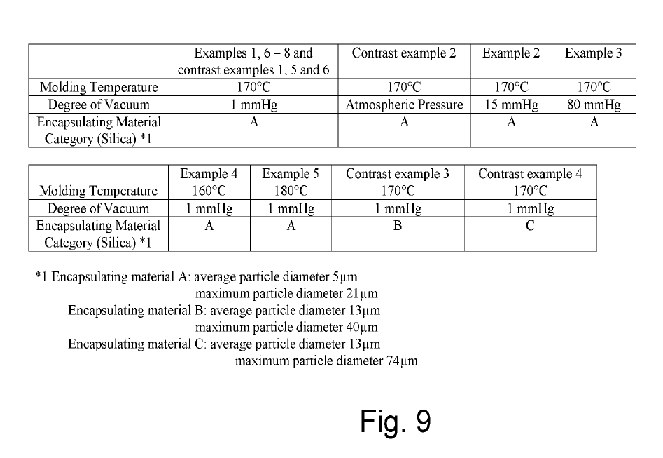

Aside from changing the degree of vacuum in example 1 to the one in FIG. 9, all other aspects are identical. A chip package structure identical to FIG. 4C is produced.

### EXAMPLE 3

Aside from changing the degree of vacuum in example 1 to the one in FIG. 9, all other aspects are identical. A chip package structure identical to FIG. 4C is produced.

### EXAMPLE 4

Aside from changing the molding temperature in example 1 to the one in FIG. 9, all other aspects are identical. A chip package structure identical to FIG. 4C is produced.

### EXAMPLE 5

Aside from changing the molding temperature in example 1 to the one in FIG. 9, all other aspects are identical. A chip package structure identical to FIG. 4C is produced.

### CONTRAST EXAMPLE 3

Aside from changing the maximum diameter of particles constituting the encapsulating material shown in example 1 to the one in FIG. 9, all other aspects are identical. A chip package structure identical to FIG. 4C is produced.

### CONTRAST EXAMPLE 4

Aside from changing the maximum diameter of particles constituting the encapsulating material shown in example 1 to the one in FIG. 9, all other aspects are identical. A chip package structure identical to FIG. 4C is produced.

### EXAMPLE 6

Aside from changing the PFA film in example 1 to a polyamide film with a thickness 50 μm, other aspects are identical. A chip package structure identical to FIG. 4C is produced.

### EXAMPLE 7

Aside from changing the copper plate in example 1 into an aluminum plate, all other aspects are identical. A chip package structure identical to FIG. 4C is produced.

### EXAMPLE 8

Aside from changing the thickness of the PFA film in example 1 to 30 μm, an integrative molding process (all the surfaces of the chip package structure as well as everything inside the mold) is performed to produce a chip package structure with a smooth surface as shown in FIG. 4B.

### CONTRAST EXAMPLE 5

Aside from not using any film in example 8, all other aspects are identical. A chip package structure as shown in FIG. 4B is produced.

### CONTRAST EXAMPLE 6

Aside from not using any film in example 8 and changing the package thickness to 0.5 mm, all other aspects are identical. A chip package structure as shown in FIG. 4B is produced.

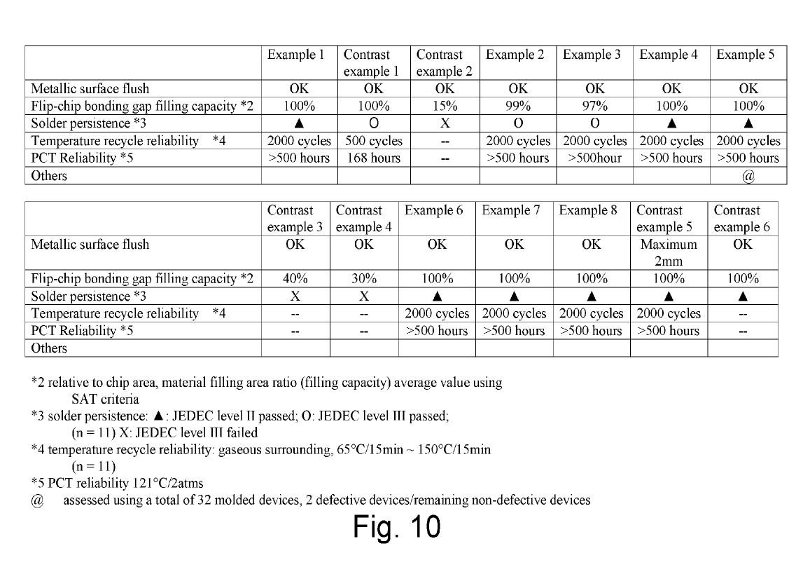

In the aforementioned examples and contrast examples, the testing conditions and results of various chip package structures are listed in FIGS. 9 and 10.

The process of fabricating a chip package structure according to the preferred embodiment of this invention is based on a technique disclosed in a Japanese pattern JP392698 (2001). This invention aims at optimizing the package dimension as well as incorporating a heat sink so that the chip package structure can have optimal reliability and heat-dissipating capacity.

In summary, this invention incorporates a heat sink into the chip package structure. Furthermore, the chip is encapsulated in a simultaneous molding process. Hence, the chip package structure has a higher level of reliability and heat-dissipating capacity than a conventional chip package structure. If an encapsulating material with a high thermal conductivity is deployed, a much higher heat-dissipating capacity can be obtained. Moreover, mass production is possible because the chip package has a simple structure,

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process for fabricating a chip package structure, comprising the steps of:
providing a carrier and a plurality of chips, wherein each chip has an active surface and at least one of the active surfaces has a plurality of bumps thereon;
connecting the chip and the carrier electrically, wherein the chip is flip-chip bonded to the carrier;
attaching a heat sink to the back of the chip through a thermal conductive adhesive layer;
attaching a heat-resistant buffering film over part of the surface of the heat sink; and
forming an encapsulating material layer over the carrier and filling a bonding gap between the chip and the carrier.

2. The process of claim 1, wherein the encapsulating material layer is formed by performing a reduced-pressure transfer molding process.

3. The process of claim 2, wherein after forming the encapsulating material layer, further comprises dicing up the carrier to form a plurality of chip package structures.

4. The process of claim 2, wherein the reduced-pressure transfer molding process is carried out at a pressure below 20 mm-Hg.

5. The process of claim 2, wherein the reduced-pressure transfer molding process is carried out at a temperature 10° C. below the melting point of the bumps.

6. The process of claim 2, wherein the encapsulating material layer between the chip and the carrier has a thickness such that maximum diameter of particles constituting the encapsulating material is less than 0.5 times the said thickness.
